(19) United States
(12) Patent Application Publication
(10) Pub. No.: US 2023/0413675 A1
(43) Pub. Date: Dec. 21, 2023

(54) PIEZOELECTRIC FILM LAMINATED BODY AND MANUFACTURING METHOD OF THE SAME

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP)

(72) Inventors: AKIHIKO TESHIGAHARA, Nisshin-shi (JP); HIDEO YAMADA, Nisshin-shi (JP); RYUICHIRO ABE, Nisshin-shi (JP); KENJI KIJIMA, Nisshin-shi (JP); TETSUYA ENOMOTO, Nisshin-shi (JP)

(21) Appl. No.: 18/330,988

(22) Filed: Jun. 7, 2023

(30) Foreign Application Priority Data
Jun. 9, 2022 (JP) 2022-093842

(51) Int. Cl. H10N 30/00; H10N 30/853; H10N 30/076; H10N 30/079

(52) U.S. Cl. CPC H10N 30/10516; H10N 30/079; H10N 30/076; H10N 30/853

(57) ABSTRACT

A piezoelectric film laminated body includes a base member and a scandium-containing aluminum nitride film. The base member has a base surface. The scandium-containing aluminum nitride film is disposed in contact with the base surface of the base member. A surface roughness of the base surface is 0.5 nm or less in arithmetic average roughness.

### CROSS REFERENCE TO RELATED APPLICATION

The present application claims the benefit of priority from Japanese Patent Application No. 2022-093842 filed on Jun. 9, 2022. The entire disclosure of the above application is incorporated herein by reference.

### TECHNICAL FIELD

The present disclosure relates to a piezoelectric film laminated body and a manufacturing method of a piezoelectric film laminated body.

### BACKGROUND

There has been known a piezoelectric film laminated body including a base member and a scandium-containing aluminum nitride (ScAlN) film that is a piezoelectric film.

### SUMMARY

The present disclosure provides a piezoelectric film laminated body that includes a base member having a base surface, and a ScAlN film disposed in contact with the base surface, and a surface roughness of the base surface is 0.5 nm or less in arithmetic average roughness. The present disclosure also provides a manufacturing method of a piezoelectric film laminated body in which a surface roughness of a base surface of a base member with which a ScAlN film is in contact is 0.5 nm or less in arithmetic average roughness.

### BRIEF DESCRIPTION OF DRAWINGS

Objects, features and advantages of the present disclosure will become apparent from the following detailed description made with reference to the accompanying drawings. In the drawings:

FIG. 1 is a cross-sectional view of a piezoelectric film laminated body according to a first embodiment;

FIG. 2 is a flowchart illustrating a manufacturing method of the piezoelectric film laminated body according to the first embodiment;

FIG. 3 is a diagram showing a crystal structure of ScAlN;

FIG. 4 is a graph showing the relationship between the surface roughness Ra of a base surface and the crystallinity in Examples 1 to 3 and Comparative Examples 1 to 3;

FIG. 5A is a SEM image of the ScAlN film of Example 1;

FIG. 5B is a SEM image of the ScAlN film of Example 2;

FIG. 5C is a SEM image of the ScAlN film of Example 3;

FIG. 5D is a SEM image of the ScAlN film of Comparative Example 1;

FIG. 5E is a SEM image of the ScAlN film of Comparative Example 2;

FIG. 6 is a graph showing the relationship between the surface roughness Ra of the base surface and the piezoelectric performance in Examples 1 to 3 and Comparative Examples 1 to 3;

FIG. 7 is a graph showing the relationship between the surface roughness Ra of the base surface and the tan 5 in Examples 1 to 3 and Comparative Examples 1 to 3;

FIG. 8 is a graph showing the relationship between the surface roughness Ra of the base surface and the crystallinity in Examples 1 to 4 and Comparative Examples 1 to 3;

FIG. 9 is a cross-sectional view of a piezoelectric film laminated body according to a second embodiment;

FIG. 10 is a cross-sectional view of a piezoelectric film laminated body according to a third embodiment;

FIG. 11 is a cross-sectional view of a piezoelectric film laminated body according to a fourth embodiment;

FIG. 12 is a cross-sectional view of a piezoelectric film laminated body according to a fifth embodiment;

FIG. 13 is a graph showing the relationship between the surface roughness Ra of the base surface and the crystallinity in Examples 1 to 3 and 5 and Comparative Examples 1 to 4;

FIG. 14 is a cross-sectional view of a piezoelectric film laminated body according to a sixth embodiment;

FIG. 15 is a cross-sectional view of a piezoelectric film laminated body according to a seventh embodiment; and

FIG. 16 is a flowchart illustrating a manufacturing method of a piezoelectric film laminated body according to an eighth embodiment.

### DETAILED DESCRIPTION

Next, a relevant technology is described only for understanding the following embodiments. A ScAlN film is a hexagonal crystal and has a polycrystalline crystal structure having multiple crystal grains. When the crystal grains include a large number of c-axis oriented crystal grains in which the c-axis of the hexagonal crystal is oriented in a direction perpendicular to a film surface of the ScAlN film, the piezoelectricity of the ScAlN film increases. On the other hand, when the crystal grains include a large number of abnormal grains in which the orientation of the c-axis of the hexagonal crystal is random, the piezoelectricity of the ScAlN film decreases. The number of c-axis oriented crystal grains present in the ScAlN film increases with decrease of the number of abnormal grains present in the ScAlN film. Therefore, it is desired to restrict the generation of abnormal grains in the ScAlN film.

According to a first aspect of the present disclosure, a piezoelectric film laminated body includes a base member having a base surface, and a ScAlN film disposed in contact with the base surface. A surface roughness of the base surface is 0.5 nm or less in arithmetic average roughness.

In the above-described configuration, the ScAlN film is disposed in contact with the base surface having the surface roughness of 0.5 nm or less. As a result, the generation of abnormal grains in the ScAlN film can be restricted as compared with a case where the ScAlN film is formed in contact with the base surface having a surface roughness larger than 0.5 nm. Therefore, it is possible to provide the piezoelectric film laminated body including the ScAlN film in which the generation of abnormal grains is restricted.

According to a second aspect of the present disclosure, a manufacturing method of a piezoelectric film laminated body includes preparing a base member having a base surface, planarizing the base surface, and forming a ScAlN film in contact with the base surface after planarizing the base surface. The planarizing the base surface is performed such that a surface roughness of the base surface is 0.5 nm or less in arithmetic average roughness.

In the above-described manufacturing method, the ScAlN film is formed in contact with the base surface having the surface roughness of 0.5 nm or less. As a result, the generation of abnormal grains in the ScAlN film can be restricted as compared with a case where the ScAlN film is formed in contact with the base surface having a surface roughness larger than 0.5 nm. Therefore, it is possible to manufacture the piezoelectric film laminated body including the ScAlN film in which the generation of abnormal grains is restricted.

According to a third aspect of the present disclosure, a manufacturing method of a piezoelectric film laminated body includes preparing a conductive member having a surface, planarizing the surface of the conductive member, forming a base member in contact with the surface of the conductive member after planarizing the surface, and forming a ScAlN film in contact with a base surface of the base member. The planarizing the conductive member is performed such that a surface roughness of the surface of the conductive member is 0.5 nm or less in arithmetic average roughness, so that a surface roughness of the base surface of the base member formed on the conductive member is 0.5 nm or less in arithmetic average roughness.

In the above-described manufacturing method, the ScAlN film is formed in contact with the base surface having the surface roughness of 0.5 nm or less. As a result, the generation of abnormal grains in the ScAlN film can be restricted as compared with a case where the ScAlN film is formed in contact with the base surface having a surface roughness larger than 0.5 nm. Therefore, it is possible to manufacture the piezoelectric film laminated body including the ScAlN film in which the generation of abnormal grains is restricted.

Hereinafter, embodiments of the present disclosure will be described with reference to the drawings. In the following embodiments, the same or equivalent parts are denoted by the same reference numerals.

### First Embodiment

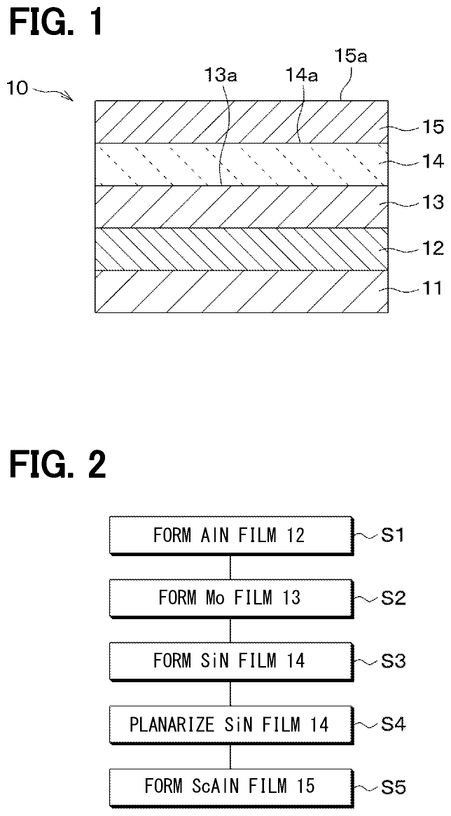

As shown in FIG. 1, a piezoelectric film laminated body 10 according to a first embodiment includes an silicon (Si) substrate 11, an aluminum nitride (AlN) film 12, a molybdenum (Mo) film 13, a silicon nitride (SiN) film 14, and a scandium-containing aluminum nitride (ScAlN) film 15. These films are laminated.

The Si substrate 11 is a substrate mainly composed of Si which is a semiconductor material. A substrate made of a semiconductor material other than Si may also be used.

The AlN film 12 is disposed above the Si substrate 11 and in contact with a surface of the Si substrate 11. The AlN film 12 is a film mainly composed of aluminum nitride. The AlN film 12 is used as a base member of the Mo film 13 for improving the crystallinity of the Mo film 13.

The Mo film 13 is disposed above the AlN film 12 and in contact with a surface of the AlN film 12. In other words, the Mo film 13 is disposed below the SiN film 14 and in contact with the SiN film 14. A lower side of the SiN film 14 is a side opposite to the ScAlN film 15 across the SiN film 14.

The Mo film 13 is a film mainly composed of Mo which is a conductive material. The Mo film 13 is used as a lower electrode for exerting the piezoelectric function of the ScAlN film 15. The Mo film 13 has a surface 13a being in contact with the SiN film 14. Instead of the Mo film 13, a film made of a conductive material such as a metal material other than Mo may also be used.

The SiN film 14 is disposed above the Mo film 13 and in contact with the surface 13a of the Mo film 13. The SiN film 14 is a base member of the ScAlN film 15 and has a film shape. The SiN film 14 as the base member is in contact with the ScAlN film 15 and supports the ScAlN film 15. The SiN film 14 is mainly composed of SiN which is an amorphous insulating material.

Amorphous is a state of matter that does not have a crystal structure. The fact that a material constituting the SiN film 14 is amorphous is confirmed by performing electron diffraction measurement on the SiN film 14. When the measurement result is a halo pattern, the material constituting the SiN film 14 is amorphous. In the present disclosure, the term “insulating” means that an electrical resistivity (that is, a volume resistivity) is 10⁴ Ω·m or more.

If the thickness of the SiN film 14, which is insulating, is too large, the overall piezoelectricity of a composite film including the ScAlN film 15 and the SiN film 14 is impaired. Therefore, the film thickness of the SiN film 14 is preferably 1/10 or less of the film thickness of the ScAlN film 15, and more preferably 1/50 or less of the film thickness of the ScAlN film 15 so that the piezoelectricity of the composite film is not significantly impaired. According to this configuration, it is possible to restrict a decrease in the overall piezoelectricity of the composite film including the ScAlN film 15 and the SiN film 14.

The SiN film 14 has a base surface 14a being in contact with the ScAlN film 15. The surface roughness of the base surface 14a is 0.5 nm or less in arithmetic average roughness. Arithmetic average roughness is defined in JIS B 0601. The surface roughness can be measured by scanning the surface with an atomic force microscope, a stylus surface roughness meter, or the like. When another film is formed on the surface to be measured, the surface roughness can be measured by observing a cross section with a transmission electron microscope and determining the shape of the interface to be measured.

The ScAlN film 15 is disposed on an upper side of the SiN film 14 in contact with the base surface 14a of the SiN film 14. The ScAlN film 15 is a piezoelectric film made of scandium-containing aluminum nitride. The ScAlN film 15 has a surface 15a on a side opposite to the SiN film 14.

The Sc concentration of the ScAlN film 15 may be any concentration within a range from 0 at % to 45 at % both inclusive. The Sc concentration is a proportion of the number of scandium atoms in total of the number of the scandium atoms and the number of aluminum atoms as 100 at %. At % refers to atomic percent. Sc concentration is measured by Rutherford backscattering spectrometry (RBS). The Sc concentrations described in the present disclosure are values measured under the following measurement conditions using the following apparatus.

Name of Apparatus: Pelletron 3SDH manufactured by National Electrostatics Corporation
Measurement Conditions
RBS Measurement
Incident Ion: 4 He++
Incident Energy: 2300 keV
Incident Angle: 0 deg
Scattering Angle: 160 deg
Sample Current: 13 nA
Beam Diameter: 2 mmφ
In-plane Rotation: None
Irradiation: 70 μC

Next, a manufacturing method the piezoelectric film laminated body 10 of the present embodiment will be described. As shown in FIG. 2, the manufacturing method of the piezoelectric film laminated body 10 includes a process S1 of forming the AlN film 12, a process S2 of forming the Mo film 13, a process S3 of forming the SiN film 14, a process S4 of planarizing the SiN film 14, and a process S5 of forming the ScAlN film 15.

First, in the process S1, the AlN film 12 is formed on the surface of the Si substrate 11 by a reactive direct current (DC) sputtering method. Thereafter, the process S2 of forming the Mo film 13 is performed.

In the process S2, the Mo film 13 is formed on the surface of the AlN film 12 by the DC sputtering method. Thereafter, the process S3 of forming the SiN film 14 is performed.

In the process S3, the SiN film 14 is formed on an upper side of the Mo film 13 so as to be in contact with the surface 13a of the Mo film 13 by a plasma chemical vapor deposition (CVD) method. Thereafter, the process S4 of planarizing the SiN film 14 is performed.

In the process S4, the base surface 14a of the SiN film 14 is planarized by etching using Ar plasma. At this time, the surface roughness of the base surface 14a is reduced with increase of the etching time. The etching time is set so that the surface roughness of the base surface 14a is 0.5 nm or less in arithmetic average roughness. After the base surface 14a is planarized, the process S5 of forming the ScAlN film 15 is performed.

In the process S5, the ScAlN film 15 is formed on the upper side of the SiN film 14 so as to be in contact with the base surface 14a by the reactive DC sputtering method. In this manner, the piezoelectric film laminated body 10 having the structure shown in FIG. 1 is manufactured.

In the present embodiment, the process S1 of forming the AlN film 12, the process S2 of forming the Mo film 13, and the process S3 of forming the SiN film 14 correspond to preparing the base member. The process S4 of planarizing the SiN film 14 corresponds to planarizing the base surface. The process S5 of forming the ScAlN film 15 corresponds to forming the ScAlN film in contact with the base surface.

The surface of the Mo film 13 may be planarized after the process S2 of forming the Mo film 13 and before the process S3 of forming the SiN film 14. Also in this case, the surface roughness of the base surface 14a is finally set to 0.5 nm or less in arithmetic average roughness by performing the process S4 of planarizing the SiN film 14.

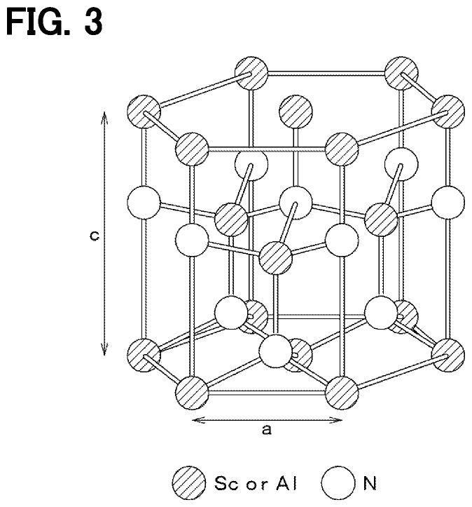

The ScAlN film 15 has a hexagonal crystal structure shown in FIG. 3 and has a polycrystalline structure having multiple crystal grains. When the crystal grains include a large number of c-axis oriented crystal grains in which the c-axis of the hexagonal crystal is oriented in a direction perpendicular to the surface 15a of the ScAlN film 15, the piezoelectricity of the ScAlN film increases. On the other hand, when the crystal grains include a large number of abnormal grains in which the orientation of the c-axis of the hexagonal crystal is random, the piezoelectricity of the ScAlN film 15 decreases. The number of c-axis oriented crystal grains present in the ScAlN film 15 increases with decrease of the number of abnormal grains present in the ScAlN film 15. Therefore, it is desired to restrict the generation of abnormal grains in the ScAlN film 15.

As will be described later, the present inventors have found that one of the causes of the generation of abnormal grains is the surface roughness of the base surface 14a. Furthermore, the present inventors have found that the formation of the ScAlN film 15 in contact with the base surface 14a having a surface roughness of 0.5 nm or less can restrict the generation of abnormal grains in the ScAlN film 15.

Therefore, the piezoelectric film laminated body 10 of the present embodiment includes the SiN film 14 having the base surface 14a and the ScAlN film 15 disposed in contact with the base surface 14a. The surface roughness of the base surface 14a in contact with the ScAlN film 15 is 0.5 nm or less in arithmetic average roughness.

The manufacturing method of the piezoelectric film laminated body 10 of the present embodiment includes preparing the SiN film 14 having the base surface 14a, planarizing the base surface 14a, and forming the ScAlN film 15 in contact with the base surface 14a. In the planarization, the surface roughness of the base surface 14a is set to 0.5 nm or less in arithmetic average roughness.

Accordingly, the ScAlN film 15 is formed in contact with the base surface 14a having the surface roughness of 0.5 nm or less. As a result, the generation of abnormal grains in the ScAlN film 15 can be restricted as compared with a case where the ScAlN film 15 is formed in contact with the base surface having a surface roughness larger than 0.5 nm.

Further, according to the piezoelectric film laminated body 10 of the present embodiment, the following effects can be obtained. The SiN film 14, which is the base member of the ScAlN film 15, is made of the amorphous insulating material.

Unlike the present embodiment, in a case where the Mo film 13 is used as a base member of the ScAlN film 15, that is, in a case where the ScAlN film 15 is formed in contact with the surface 13a of the Mo film 13, abnormal grains are likely to be generated in the ScAlN film 15. The cause of generating abnormal grains is considered as follows.

In general, a Mo film formed on a surface of an AlN film is likely to be (101) oriented. That is, a plane direction parallel to a surface of the Mo film formed on the surface of the AlN film is likely to be a (101) plane. In this case, the symmetry of the atomic arrangement of Mo in the plane direction parallel to the surface 13a of the Mo film 13 is similar to the symmetry of the atomic arrangement of ScAlN in the plane direction parallel to the surface 15a of the ScAlN film 15 when multiple crystal grains are oriented such that the c-axis of the hexagonal crystal is perpendicular to the surface 15a of the ScAlN film 15. In addition, a lattice constant of Mo does not match a lattice constant of ScAlN within a range of about several percent. Therefore, at the time of forming the ScAlN film 15, undesired strain, that is, stress is generated in the ScAlN film 15. These are considered to be the cause of generating abnormal grains in the above case.

In contrast, according to the present embodiment, the atomic arrangement of SiN in the plane direction parallel to the base surface 14a of the SiN film 14 is different from the atomic arrangement of ScAlN in the plane direction parallel to the surface 15a of the ScAlN film 15 when the multiple crystal grains are oriented. Thus, the a piezoelectric film laminated body 10 of the present embodiment can restrict the generation of abnormal grains that are generated when the symmetry of the atomic arrangement in the plane direction parallel to the base surface 14a is the same as the symmetry of the atomic arrangement in the plane direction parallel to the surface 15a of the ScAlN film 15, and the lattice constant of the base member does not match the lattice constant of ScAlN. In this way, the generation of abnormal grains in the ScAlN film 15 can be restricted also because the base member is made of amorphous insulating material.

The following describes the results of experiments conducted by the present inventors. The present inventors manufactured the piezoelectric film laminated bodies 10 of Examples 1 to 3 by the manufacturing method described above. In addition, the present inventors manufactured piezoelectric film laminated bodies 10 of Comparative Examples 1 to 3 by changing the condition of the process S4 of planarizing the SiN film 14 with respect to the manufacturing method described above. Then, the present inventors measured the surface roughness Ra of the base surface of the SiN film 14, and the crystallinity, the piezoelectric performance, and tan 5 of the ScAlN film 15 in each of the piezoelectric film laminated bodies 10 of Example 1 to 3 and Comparative Example 1 to 3. The manufacturing conditions of the piezoelectric film laminated bodies 10 of Examples 1 to 3 and Comparative Examples 1 to 3 were set as follows.

<Process of Forming SiN Film 14>
Apparatus: RF plasma apparatus of parallel plate type
Introduced Gas: SiH₄, NH₃, N₂
Gas Pressure: 5 Tor
RF Power: 300 W
Substrate Temperature: 330° C.

<Process of Planarizing SiN Film 14>
Apparatus: RF plasma apparatus of parallel plate type
Introduced Gas: Ar
RF Power: 50 W
Etching Time: 0 to 200 sec

<Etching Time and Surface Roughness Ra in Process of Planarizing SiN Film 14>

In Example 1, the etching time was 200 sec, and the surface roughness Ra was 0.29 nm. In Example 2, the etching time was 90 sec, and the surface roughness Ra was 0.44 nm. In Example 3, the etching time was 40 sec, and the surface roughness Ra was 0.51 nm. In Comparative Example 1, the etching time was 30 sec, and the surface roughness Ra was 0.57 nm. In Comparative Example 2, the etching time was 23 sec, and the surface roughness Ra was 0.71 nm. In Comparative Example 3, the etching time was 0 sec, and the surface roughness Ra was 1.01 nm.

<Process of Forming ScAlN Film 15>
Target Type: ScAl target with Sc concentration of 40%
Target Size: 300 mm in diameter
Distance between Si Substrate and Target: 60 mm
DC Power: 8 kW
Gas Flow Rate N₂: 26 sccm, Ar: 19 sccm
Gas Pressure: 0.3 Pa
Si Substrate Temperature: 335° C.
Substrate RF Bias Power: 20 W

As a result of measuring the Sc concentration of the ScAlN film by RBS, the Sc concentration of each of the ScAlN films of Examples 1 to 3 and Comparative Examples 1 to 3 was 40%.

<Thickness of Each Film>

Thickness of AlN Film 12: 30 nm
Thickness of Mo Film 13: 25 nm
Thickness of the SiN Film 14: 10 to 30 nm
Thickness of ScAlN Film 15: 500 nm

The thickness of the SiN film 14 was different among Examples 1 to 3 and Comparative Examples 1 to 3. This is because the etching time was different.

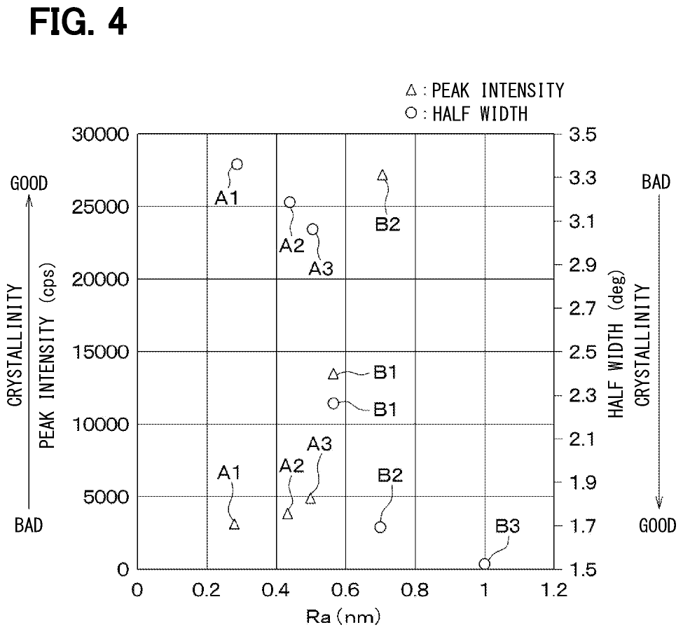

FIG. 4 is a graph showing the relationship between the surface roughness Ra of the base surface 14a and the crystallinity of the ScAlN film 15 of each of Examples 1 to 3 and Comparative Examples 1 to 3. The vertical axis of FIG. 4 indicates a peak intensity and a half width of a rocking curve of an X-ray diffraction peak of a (0002) plane of a ScAlN crystal measured by an X-ray diffraction apparatus. The horizontal axis of FIG. 4 indicates the surface roughness Ra of the base surface 14a.

In FIG. 4 and FIGS. 6 to 8, A1 to A3 indicate the results of Examples 1 to 3, respectively. In addition, B1 to B3 indicate the results of Comparative Examples 1 to 3, respectively. The crystallinity of ScAlN is good when the peak intensity is large and the half width is small. The phrase “the crystallinity of ScAlN is good” means that the amount of abnormal grains included in the ScAlN film 15 is small and the amount of c-axis oriented crystal grains included in the ScAlN film 15 is large. That is, the phrase “the crystallinity of ScAlN is good” means that the crystal structure of ScAlN has a high orientation in which the c-axis of the hexagonal crystal is oriented in a direction perpendicular to the surface 15a of the ScAlN film 15.

As can be seen from FIG. 4, with decrease of the surface roughness Ra, the peak intensity tends to increase and the half width tends to decrease, that is, the crystallinity tends to improve. In particular, when the surface roughness Ra changes from 0.57 of B1 to 0.51 of A3, the crystallinity rapidly improves. 0.51 rounded off to one decimal place is 0.5, and 0.57 rounded off to one decimal place is 0.6. Thus, it is considered that when the surface roughness Ra of the base surface is 0.5 or less, the ScAlN film 15 having better crystallinity is obtained than when the surface roughness Ra of the base surface is larger than 0.5.

The surface roughness Ra of the base surface 14a of each of Examples 1 to 3 is included in a range of 0.5 nm or less. The surface roughness Ra of the base surface 14a of each of Comparative Examples 1 to 3 is included in a range larger than 0.5 nm.

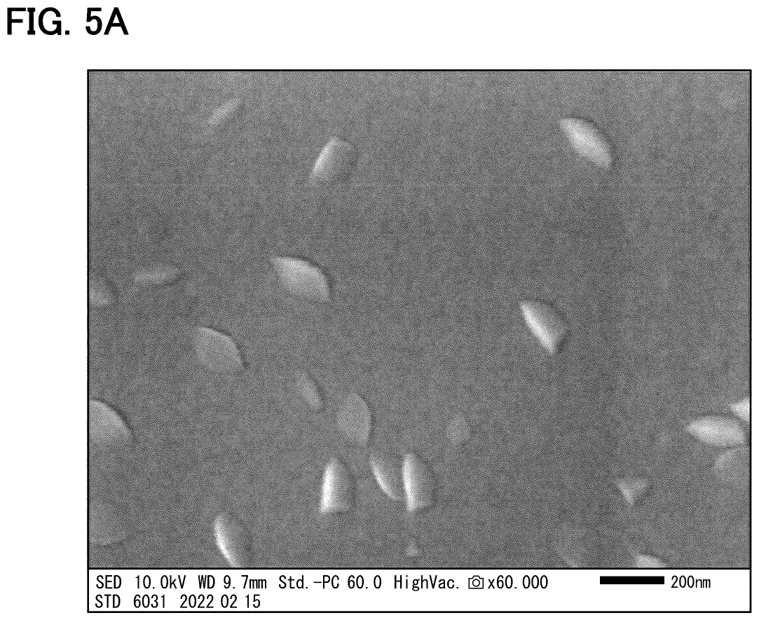

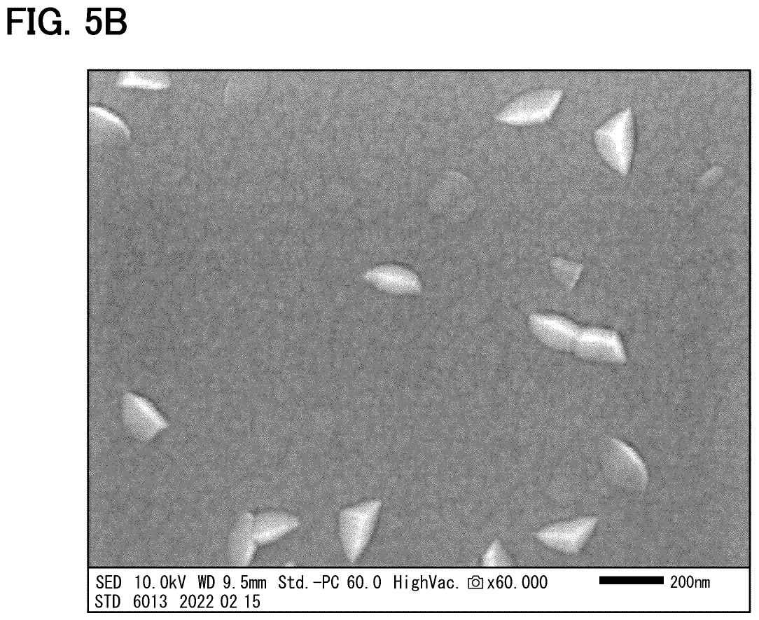

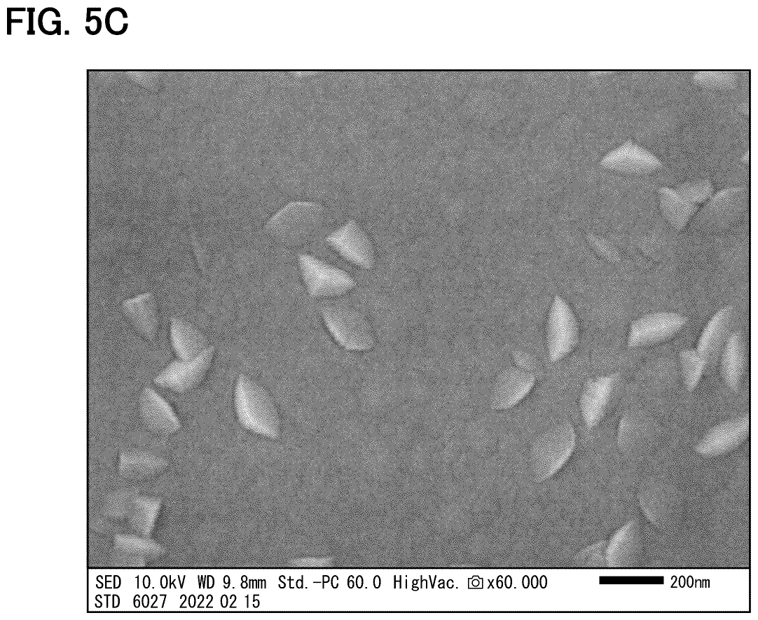

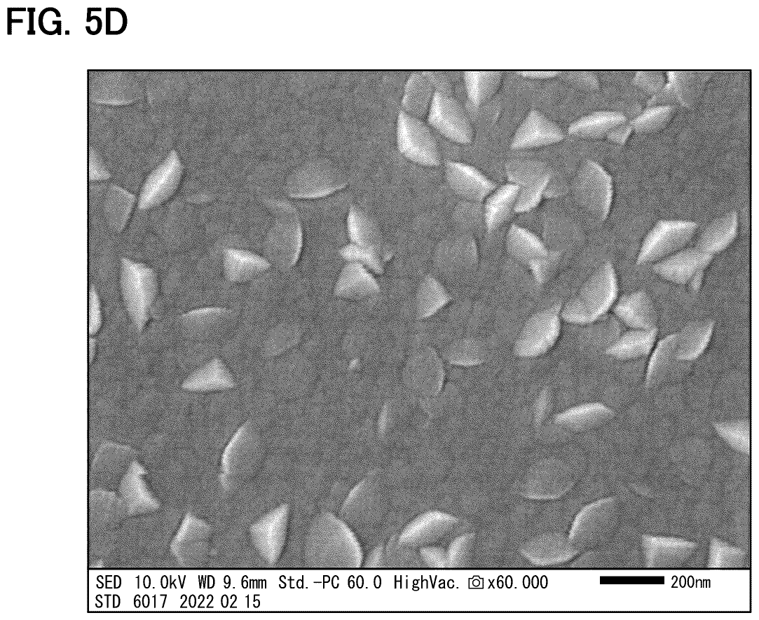

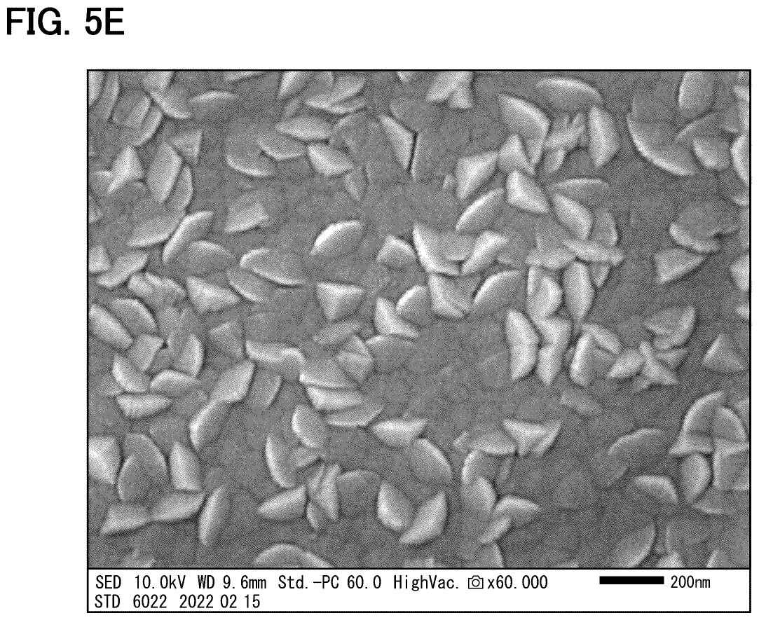

FIGS. 5A to 5C are SEM images of the ScAlN films 15 of Examples 1 to 3, respectively. FIGS. 5D and 5E are SEM images of the ScAlN films 15 of Comparative Examples 1 and 2, respectively. The SEM images are images acquired by a scanning electron microscope. Multiple small pieces present in each image are abnormal grains. From FIGS. 5A to 5E, it was confirmed that the amounts of the abnormal grains included in the ScAlN films 15 of Examples 1 to 3 were smaller than those in the ScAlN films 15 of Comparative Examples 1 and 2.

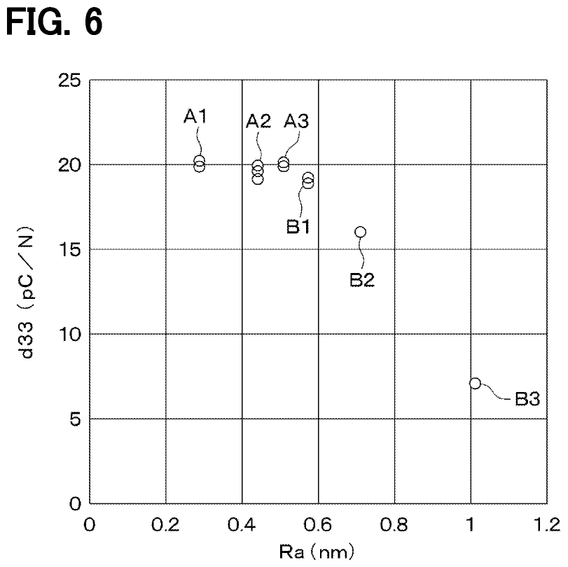

FIG. 6 is a graph showing the relationship between the surface roughness Ra of the base surface 14a and the piezoelectric performance of the ScAlN film 15 of each of Examples 1 to 3 and Comparative Examples 1 to 3. The vertical axis of FIG. 6 indicates a piezoelectric constant d33. It is desirable that the value of the piezoelectric constant d33 is large. From FIG. 6, it was confirmed that the piezoelectric constants d33 of the ScAlN films 15 of Examples 1 to 3 were larger than the piezoelectric constants d33 of the ScAlN films 15 of Comparative Examples 1 to 3.

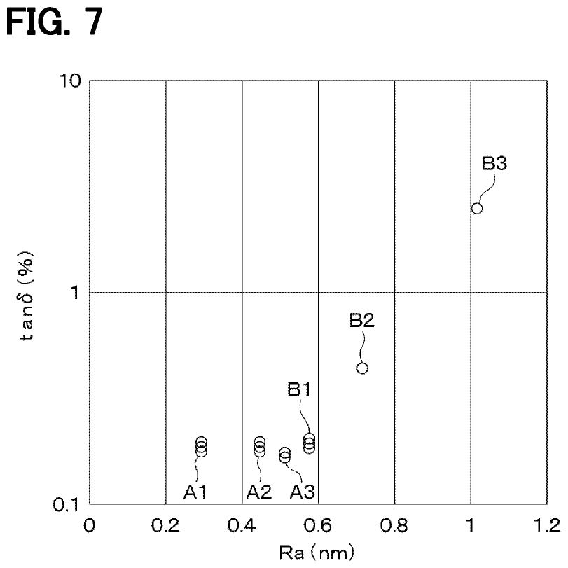

FIG. 7 is a graph showing the relationship between the surface roughness Ra of the base surface 14a and the tan b of the ScAlN film 15 of each of Examples 1 to 3 and Comparative Examples 1 to 3. It is desirable that the value of the tan 5 is small. From FIG. 7, it was confirmed that the tan 5 of the ScAlN films 15 of Examples 1 to 3 were smaller than the tan 5 of the ScAlN films 15 of Comparative Examples 1 to 3.

In addition, the present inventors manufactured a piezoelectric film laminated body 10 of Example 4. In Example 4, the Sc concentration of the ScAlN film 15 is 24%. The surface roughness Ra of the base surface 14a of the SiN film 14 is 0.25 nm. Other manufacturing conditions of the piezoelectric film laminated body 10 were the same as those in Examples 1 to 3.

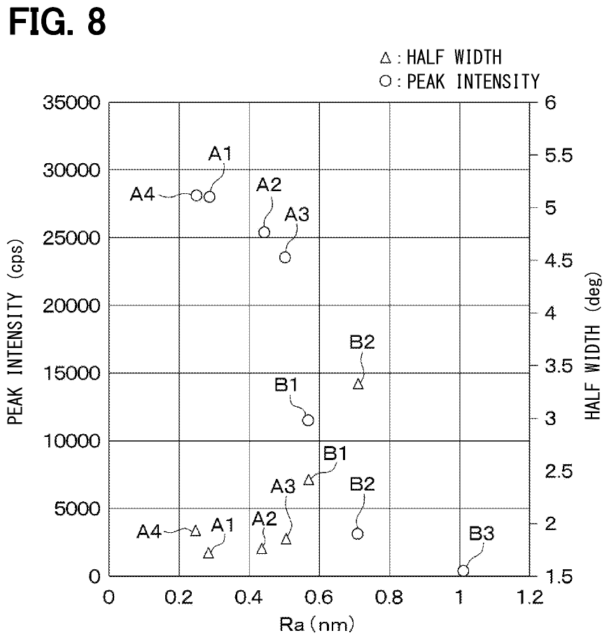

Then, the present inventors measured the crystallinity of the ScAlN film 15 of Example 4 in the same manner as in Examples 1 to 3. FIG. 8 is a graph obtained by adding the measurement results of the surface roughness Ra and the crystallinity of Example 4 to the graph of Examples 1 to 3 and Comparative Examples 1 to 3. A4 in FIG. 8 is the measurement result of Example 4. The surface roughness Ra of the base surface 14a of Example 4 is 0.5 nm or less. From FIG. 8, it was confirmed that Example 4 also satisfies the relationship of good crystallinity when the surface roughness Ra of the base surface 14a is 0.5 nm or less.

From the results of Examples 1 to 4, it was confirmed that when the Sc concentration of the ScAlN film 15 is 24 at % or more and 40 at % or less, the surface roughness Ra of the base surface 14a is 0.5 nm or less, and thus the generation of abnormal grains in the ScAlN film 15 can be restricted as compared with the case where the surface roughness Ra is more than 0.5 nm. Not only when the Sc concentration of the ScAlN film 15 is 24 at % or more and 40 at % or less, but also when the Sc concentration is less than 24 at %, it is considered that the similar effect can be obtained.

However, the present inventors have found that abnormal grains are likely to generate when the base surface 14a is not planarized unlike the manufacturing method of the piezoelectric film laminated body 10 according to the present embodiment, particularly when the Sc concentration is as high as 24 at % or more. Therefore, as shown in the above experimental results, it is particularly effective that the surface roughness Ra is 0.5 nm or less when the Sc concentration is 24 at % or more.

In the present embodiment, the SiN film 14 is used as the base member of the ScAlN film 15. However, a film made of an amorphous insulating material other than SiN may also be used. Examples of the amorphous insulating material other than SiN include SiO₂. The film made of amorphous SiO₂ is formed by being deposited on a conductive material such as the Mo film 13.

### Second Embodiment

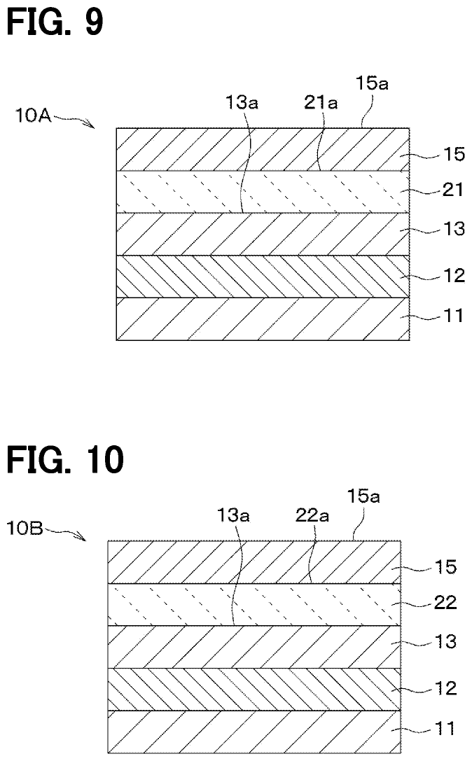

In a piezoelectric film laminated body 10A of a second embodiment, as shown in FIG. 9, an aluminum nitride (AlN) film 21 is used as a base member of the ScAlN film 15 instead of the SiN film 14 of the first embodiment. The AlN film 21 is a film mainly composed of AlN. AlN constituting the AlN film 21 is an insulating material that is polycrystalline including multiple crystal grains, and each of the crystal grains has a non-oriented structure. “Non-oriented” means a state in which the orientation distribution of each of the crystal grains is uniform. In terms of actual measurement, “non-oriented” means a state in which a peak is not shown when a rocking curve regarding an any crystal plane is measured in X-ray diffraction. In the measurement of the rocking curve, the horizontal axis indicates an angle ω of a sample with respect to an incident X-ray, and the vertical axis indicates a diffraction intensity. Not showing a peak means that the diffraction intensity is a substantially constant value with respect to a change in the angle ω.

The AlN film 21 has a base surface 21a in contact with the ScAlN film 15. Similarly to the first embodiment, the surface roughness of the base surface 21a is 0.5 nm or less in arithmetic average roughness. The other configurations of the piezoelectric film laminated body 10A are similar to those of the piezoelectric film laminated body 10 of the first embodiment.

A manufacturing method of the piezoelectric film laminated body 10A of the present embodiment is similar to the manufacturing method of the piezoelectric film laminated body 10 of the first embodiment except that the AlN film 21 is formed instead of the SiN film 14. The AlN film 21 is formed by a sputtering method under conditions in which crystal grains are not oriented.

According to the present embodiment, effects similar to those of the first embodiment can be obtained by setting the surface roughness of the base surface 21a to 0.5 nm or less in arithmetic average roughness. Furthermore, according to the piezoelectric film laminated body 10A of the present embodiment, the following effects can be obtained.

The AlN film 21, which is the base member of the ScAlN film 15, is made of the insulating material that is polycrystalline including the multiple crystal grains, and each of the crystal grains has the non-oriented structure. According to this configuration, the atomic arrangement in the plane direction parallel to the base surface 21a of the AlN film 21 is different from the atomic arrangement of ScAlN in the plane direction parallel to the surface 15a of the ScAlN film 15 when the multiple crystal grains are oriented such that the c-axis of the hexagonal crystal is perpendicular to the surface 15a of the ScAlN film 15. Therefore, similarly to the first embodiment, it is possible to restrict the generation of abnormal grains caused by the fact that the symmetry of the atomic arrangement of the base member is the same as the atomic arrangement of ScAlN and the lattice constant of the base member does not match the lattice constant of ScAlN.

In the present embodiment, the AlN film 21 is used as the base member of the ScAlN film 15. However, not limited to the AlN film 21, another film made of an insulating material that is polycrystalline including multiple crystal grains, and in which each of the crystal grains has a non-oriented structure may also be used as a base member of the ScAlN film 15.

### Third Embodiment

In a piezoelectric film laminated body 10B of a third embodiment, as shown in FIG. 10, a molybdenum oxide (MoO₃) film 22 is used as a base member of the ScAlN film 15 instead of the SiN film 14 of the first embodiment. The MoO₃ film 22 is a film mainly composed of MoO₃. MoO₃ constituting the MoO₃ film 22 is an insulating material having an orthorhombic crystal structure. The MoO₃ film 22 may be either a polycrystal or a single crystal.

The MoO₃ film 22 has a base surface 22a in contact with the ScAlN film 15. Similarly to the first embodiment, the surface roughness of the base surface 22a is 0.5 nm or less in arithmetic average roughness. The other configurations of the piezoelectric film laminated body 10B are similar to those of the piezoelectric film laminated body 10 of the first embodiment.

A manufacturing method of the piezoelectric film laminated body 10B of the present embodiment is similar to the manufacturing method of the piezoelectric film laminated body 10 of the first embodiment except that the MoO₃ film 22 is formed instead of the SiN film 14.

According to the present embodiment, effects similar to those of the first embodiment can be obtained by setting the surface roughness of the base surface 22a to 0.5 nm or less in arithmetic average roughness. Furthermore, according to the piezoelectric film laminated body 10B of the present embodiment, the following effects can be obtained.

When the crystal grains are oriented such that the orientation of the c-axis of the hexagonal crystal is perpendicular to the surface 15a of the ScAlN film 15, a crystal plane in a plane direction parallel to the surface 15a of the ScAlN film 15 is a (0001) plane. At this time, the atomic arrangement of ScAlN in the plane direction parallel to the surface 15a of the ScAlN film 15 is six-fold rotationally symmetrical. Therefore, unlike the present embodiment, when the base member of the ScAlN film 15 has a hexagonal crystal structure and crystal grains are oriented such that the orientation of the c-axis of the hexagonal crystal is perpendicular to the surface 15a of the ScAlN film 15, abnormal grains are generated due to mismatch of lattice constants, as described in the first embodiment.

Furthermore, unlike the present embodiment, in a case where the base material has a cubic crystal structure, when the crystal plane in the plane direction parallel to the surface of the base member with which the ScAlN film 15 is in contact is a (111) plane, the atomic arrangement in the plane direction parallel to the surface of the base member is six-fold rotationally symmetrical or close to pseudo six-fold rotationally symmetrical. Therefore, abnormal grains are generated due to the mismatch of the lattice constants described above.

In contrast, according to the present embodiment, the MoO₃ film 22, which is the base member of the ScAlN film 15, is the film made of the insulating material having the crystal structure other than hexagonal and cubic. Therefore, it is possible to restrict the generation of abnormal grains caused by the mismatch of lattice constants which may occur when the base member of the ScAlN film 15 has a hexagonal or cubic crystal structure.

In the present embodiment, the MoO₃ film 22 is used as the base member of the ScAlN film 15. However, not limited to the MoO₃ film 22, another film made of an insulating material having a crystal structure other than the hexagonal crystal and the cubic crystal may be used as a base member of the ScAlN film 15.

### Fourth Embodiment

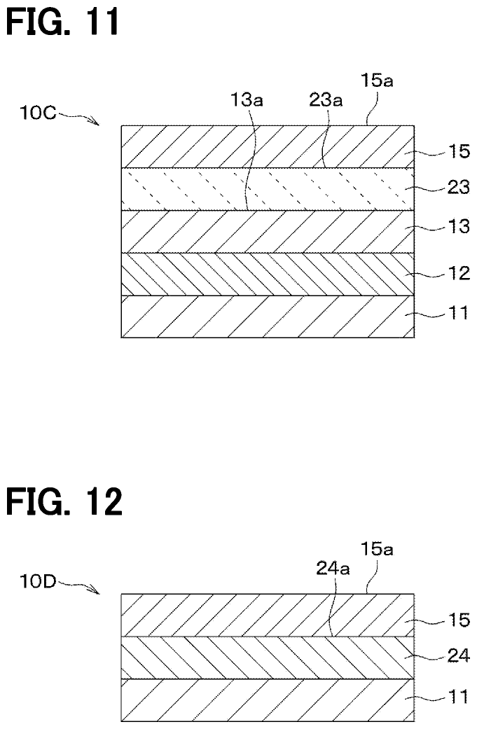

In a piezoelectric film laminated body 10C of a fourth embodiment, as shown in FIG. 11, a BN film 23 is used as a base member of the ScAlN film 15 instead of the SiN film 14 of the first embodiment. The BN film 23 is a film mainly composed of BN. The BN film 23 has a base surface 23a in contact with the ScAlN film 15. Similarly to the first embodiment, the surface roughness of the base surface 23a is 0.5 nm or less in arithmetic average roughness.

BN constituting the BN film 23 is an insulating material having a hexagonal crystal structure and a polycrystalline structure having multiple crystal grains. The crystal grains include crystal grains in which crystal axes of the crystal grains are oriented in a specific orientation. The orientation of the c-axis of the oriented crystal grains is not perpendicular to the base surface 23a. That is, BN constituting the BN film 23 has a structure excluding a structure in which the orientation of the c-axis of the hexagonal crystal is perpendicular to the base surface 23a.

BN constituting the BN film 23 may have a single crystal structure. Also in this case, the BN film 23 has a structure excluding the structure in which the orientation of the c-axis of the hexagonal crystal is perpendicular to the base surface 23a. That is, the crystal plane of the BN film 23 in the plane direction parallel to the base surface 23a is not a c-plane.

The other configurations of the piezoelectric film laminated body 10C are similar to those of the piezoelectric film laminated body 10 of the first embodiment. A manufacturing method of the piezoelectric film laminated body 10C of the present embodiment is similar to the manufacturing method of the piezoelectric film laminated body 10 of the first embodiment except that the BN film 23 is formed instead of the SiN film 14.

According to the present embodiment, effects similar to those of the first embodiment can be obtained by setting the surface roughness of the base surface 23a to 0.5 nm or less in arithmetic average roughness. Furthermore, according to the piezoelectric film laminated body 10C of the present embodiment, the following effects can be obtained.

When the base member of the ScAlN film 15 has a hexagonal crystal structure and crystal grains are oriented such that the orientation of the c-axis of the hexagonal crystal is perpendicular to the surface 15a of the ScAlN film 15, abnormal grains are generated due to mismatch of lattice constants, as described in the first embodiment.

On the other hand, the BN film 23, which is the base member of the ScAlN film 15, is the film formed of the insulating material having the hexagonal crystal structure and the structure excluding the structure in which the orientation of the c-axis of the hexagonal crystal is perpendicular to the base surface 23a. Therefore, it is possible to restrict the generation of abnormal grains caused by the mismatch of lattice constants which may occur when the base member of the ScAlN film 15 has a hexagonal structure. Not limited to the BN film 23, another film made of an insulating material having a hexagonal crystal structure and having a structure excluding the structure in which the orientation of the c-axis of the hexagonal crystal is perpendicular to a base surface 23a may also be used as a base member of the ScAlN film 15.

As the base member of the ScAlN film 15, a silicon carbide (SiC) film may also be used instead of the BN film 23 of the present embodiment. The SiC film is a film mainly composed of SiC. The SiC film has a base surface in contact with the ScAlN film 15. Also in this case, when the surface roughness of the base surface is 0.5 nm or less in arithmetic average roughness, effects similar to the effects of the first embodiment can be obtained.

In this case, SiC constituting the SiC film is an insulating material having a cubic crystal structure and a polycrystalline structure having multiple crystal grains. The crystal grains include crystal grains in which crystal axes of the crystal grains are oriented in a specific orientation. The orientation of the <111> axis of the cubic crystal of the oriented crystal grains is not perpendicular to the base surface. That is, SiC constituting the SiC film has a structure excluding a structure in which the orientation of the <111> axis of the cubic crystal is perpendicular to the base surface.

SiC constituting the SiC film may also have a single crystal structure. Also in this case, SiC constituting the SiC film has a structure excluding a structure in which the orientation of the <111> axis of the cubic crystal is perpendicular to the base surface. That is, a crystal plane in a plane direction parallel to the base surface of the SiC film is not a (111) plane.

Therefore, it is possible to restrict the generation of abnormal grains caused by the mismatch of lattice constants which may occur when the base member of the ScAlN film 15 has a cubic structure as described in the third embodiment. Not limited to the SiC film, another film made of an insulating material having a cubic crystal structure and having a structure other than a structure in which the orientation of the <111> axis of the cubic crystal is perpendicular to a base surface may also be used as a base member of the ScAlN film 15.

### Fifth Embodiment

In a piezoelectric film laminated body 10D of a fifth embodiment, as shown in FIG. 12, a polycrystalline silicon (poly-Si) film 24 is used as a base member of the ScAlN film 15 instead of the SiN film 14 of the first embodiment. The poly-Si film 24 is disposed above the Si substrate 11 and in contact with a surface of the Si substrate 11.

The poly-Si film 24 is a film mainly composed of polycrystalline silicon which is a conductive material. The poly-Si film 24 is used as a lower electrode for exerting a piezoelectric function of the ScAlN film 15. Poly-Si constituting the poly-Si film 24 has a polycrystalline structure including multiple crystal grains. Each of the crystal grains is non-oriented. Phosphorus or boron may be added to poly-Si constituting the poly-Si film 24. When phosphorous or boron is added, the conductivity is increased and the function as the lower electrode is improved.

The poly-Si film 24 has a base surface 24a in contact with the ScAlN film 15. The surface roughness of the base surface 24a is 0.5 nm or less in arithmetic average roughness. The other configurations of the piezoelectric film laminated body 10D are similar to those of the piezoelectric film laminated body 10 of the first embodiment.

A manufacturing method of the piezoelectric film laminated body 10D of the present embodiment includes a process of forming the poly-Si film 24, a process of planarizing the poly-Si film 24, and a process of forming the ScAlN film 15. First, in the process of forming the poly-Si film 24, the poly-Si film 24 is formed on the surface of the Si substrate 11 using a thermal CVD apparatus. Thereafter, the process of planarizing the poly-Si film 24 is performed. In the process of planarizing the poly-Si film 24, the base surface 24a of the poly-Si film 24 is planarized. At this time, the surface roughness of the base surface 24a is set to 0.5 nm or less in arithmetic average roughness by a method similar to the process S4 of planarizing the SiN film 14 of the first embodiment. Thereafter, the process of forming the ScAlN film 15 is performed. The process of forming the ScAlN film 15 is the same as the process S5 of the first embodiment.

According to the present embodiment, effects similar to those of the first embodiment can be obtained by setting the surface roughness of the base surface 24a to 0.5 nm or less in arithmetic average roughness. Furthermore, according to the piezoelectric film laminated body 10D of the present embodiment, the following effects can be obtained.

The poly-Si film 24, which is the base member of the ScAlN film 15, is made of the conductive material that is polycrystalline including multiple crystal grains, and each of the crystal grains has a non-oriented structure. According to this configuration, the atomic arrangement in the plane direction parallel to the base surface 24a of the poly-Si film 24 is different from the atomic arrangement of ScAlN in the plane direction parallel to the surface 15a of the ScAlN film 15 when the multiple crystal grains are oriented such that the c-axis of the hexagonal crystal is perpendicular to the surface 15a of the ScAlN film 15. Therefore, similarly to the first embodiment, it is possible to restrict the generation of abnormal grains caused by the fact that the symmetry of the atomic arrangement of the base member is the same as the atomic arrangement of ScAlN and the lattice constant of the base member does not match the lattice constant of ScAlN.

The present inventors manufactured the piezoelectric film laminated body 10D of Example 5 by the manufacturing method described above. In addition, the present inventors manufactured a piezoelectric film laminated body of Comparative Example 4 by changing a condition of planarizing the poly-Si film 24 with respect to the manufacturing method described above. The surface roughness Ra of the base surface 24a of the poly-Si film 24 is 0.45 nm in Example 5 and 1.14 nm in Comparative Example 4. Conditions of forming the ScAlN film 15 were the same as those in Examples 1 to 3. The Sc concentration of the ScAlN film 15 is 40 at % in both Example 5 and Comparative Example 4. The thickness the poly-Si film 24 is 70 nm and the thickness of the ScAlN film 15 is 500 nm.

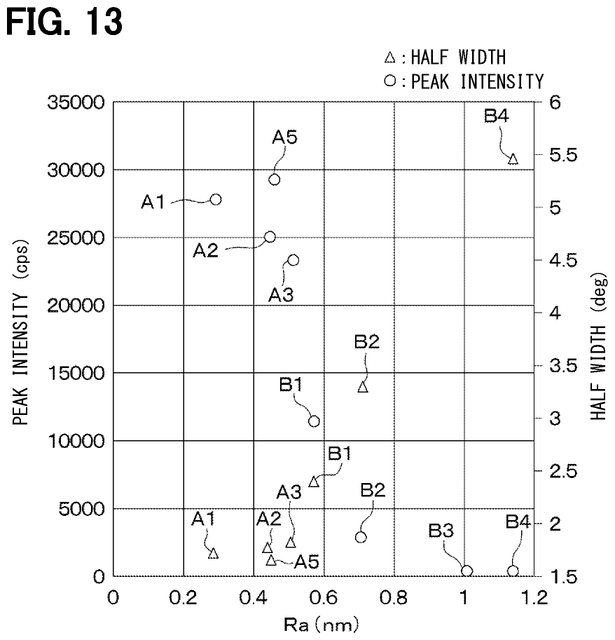

The present inventors measured the surface roughness Ra of the base surface 24a of the poly-Si film 24 and the crystallinity of the ScAlN film 15 for each of Example 5 and Comparative Example 4 in the same manner as in Examples 1 to 3. FIG. 13 is a graph obtained by adding the measurement results of the surface roughness Ra and the crystallinity of Example 5 and Comparative Example 4 to the graph of Examples 1 to 3 and Comparative Examples 1 to 3. A5 in FIG. 13 is the measurement result of Example 5. B4 in FIG. 13 is the measurement result of Comparative Example 4. The surface roughness Ra of the base surface 24a of Example 5 is 0.5 nm or less. From FIG. 13, it was confirmed that Example 5 also satisfies the relationship of good crystallinity when the surface roughness Ra of the base surface 24a is 0.5 nm or less.

In the present embodiment, the poly-Si film 24 is disposed above the Si substrate 11 and in contact with the surface of the Si substrate 11. Alternatively, an insulating film made of SiO₂ or the like may be interposed between the Si substrate 11 and the poly-Si film 24.

In the present embodiment, the poly-Si film 24 is used as the base member of the ScAlN film 15. However, not limited to the poly-Si film 24, another film made of a conductive material that is polycrystalline including multiple crystal grains, and in which each of the crystal grains has a non-oriented structure may also be used as a base member of the ScAlN film 15.

### Sixth Embodiment

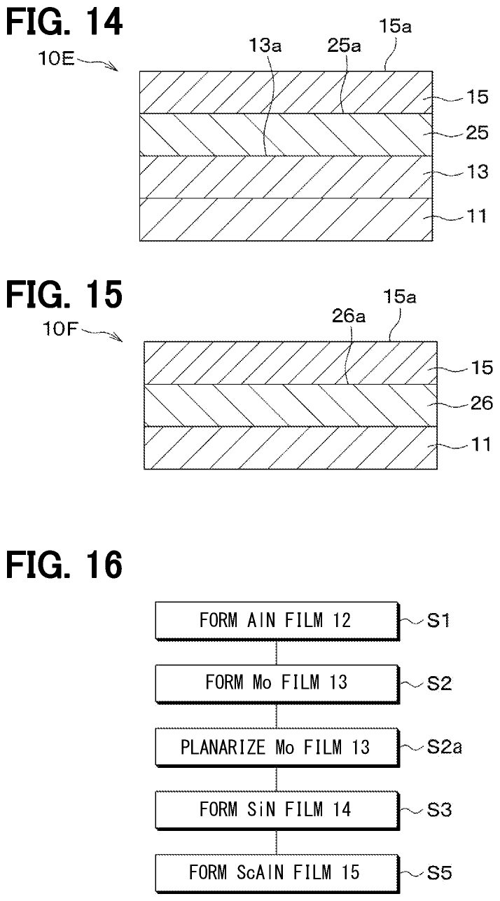

In a piezoelectric film laminated body 10E of a sixth embodiment, as shown in FIG. 14, an a-Mo film 25 is used as a base member of the ScAlN film 15 instead of the SiN film 14 of the first embodiment. The a-Mo film 25 is disposed above the Mo film 13 and in contact with the surface 13a of the Mo film 13. Although the Mo film 13 is disposed above the surface of the Si substrate 11 in contact with the surface of the Si substrate 11 in an example shown in FIG. 14, the Mo film 13 may be disposed above the AlN film 12 in contact with the AlN film 12 as in the first embodiment. The Si substrate 11, the Mo film 13, and the ScAlN film 15 are the same as those in the first embodiment.

The a-Mo film 25 is a film mainly composed of amorphous Mo which is a conductive material. In the present specification, the term “conductive” means that the electrical resistivity (that is, the volume resistivity) is 10⁻² Ω·m or less. The a-Mo film 25 is used as a lower electrode together with the Mo film 13. The a-Mo film 25 has a base surface 25a in contact with the ScAlN film 15. Similarly to the first embodiment, the surface roughness of the base surface 25a is 0.5 nm or less in arithmetic average roughness.

A manufacturing method of the piezoelectric film laminated body 10E of the present embodiment includes a process of forming the Mo film 13, a process of forming the a-Mo film 25, a process of planarizing the a-Mo film 25, and a process of forming the ScAlN film 15. First, in the process of forming the Mo film 13, the Mo film 13 is formed on the surface of the Si substrate 11 in the same manner as in the process S2 of forming the Mo film 13 of the first embodiment. Thereafter, the process of forming the a-Mo film 25 is performed. In the process of forming the a-Mo film 25, the a-Mo film 25 is formed by performing ion implantation or plasma treatment on the Mo film 13.

In the ion implantation to the Mo film 13, metal ions, rare gas ions or the like are used as ion implantation species. By applying energy of about several tens to 100 keV to the surface layer of the Mo film 13, the a-Mo film 25 having a thickness of about several tens to 100 nm can be formed. By using metal ions, rare gas ions, or the like as the ion-implanted species, the conductivity of the ion-implanted Mo can be maintained.

In the plasma treatment to the Mo film 13, a chamber configuration generally used for dry etching (that is, a layout in which a substrate and a counter electrode are arranged in parallel) is used. In this chamber configuration, plasma is generated by high-frequency discharge in the same manner as in a normal dry etching process. At this time, by introducing only AR gas as material gas, etching of the Mo film 13 can be minimized, and the surface layer of the Mo film 13 can be amorphized.

Thereafter, the process of planarizing the a-Mo film 25 is performed. In the process of planarizing the a-Mo film 25, the base surface 25a of the a-Mo film 25 is planarized. At this time, the surface roughness of the base surface 25a is set to 0.5 nm or less in arithmetic average roughness by a method similar to the process S4 of planarizing the SiN film 14 of the first embodiment. Thereafter, the process of forming the ScAlN film 15 is performed. The process of forming the ScAlN film 15 is the same as the process S5 of the first embodiment. Note that a process of planarizing the Mo film 13 may be performed instead of the process of planarizing the a-Mo film 25. In this case, the process of forming the Mo film 13, the process of planarizing the Mo film 13, and the process of forming the a-Mo film 25 are performed in this order. In the process of planarizing the Mo film 13, as in an eighth embodiment described later, the surface roughness of the surface of the Mo film 13 is set to 0.5 nm or less in arithmetic average roughness, so that the surface roughness of the a-Mo film 25 formed in the subsequent process can be 0.5 nm or less in arithmetic average roughness.

According to the present embodiment, effects similar to those of the first embodiment can be obtained by setting the surface roughness of the base surface 25a to 0.5 nm or less in arithmetic average roughness. Furthermore, according to the piezoelectric film laminated body 10E of the present embodiment, the following effects can be obtained.

The a-Mo film 25 which is the base member of the ScAlN film 15 is a film of the amorphous conductive material. According to this configuration, the atomic arrangement in the plane direction parallel to the base surface 25a of the a-Mo film 25 is different from the atomic arrangement of ScAlN in the plane direction parallel to the surface 15a of the ScAlN film 15 when the multiple crystal grains are oriented such that the c-axis of the hexagonal crystal is perpendicular to the surface 15a of the ScAlN film 15. Therefore, similarly to the first embodiment, it is possible to restrict the generation of abnormal grains caused by the fact that the symmetry of the atomic arrangement of the base member is the same as the atomic arrangement of ScAlN and the lattice constant of the base member does not match the lattice constant of ScAlN.

In the piezoelectric film laminated body 10E of the present embodiment, the a-Mo film 25 is used as the base member of the ScAlN film 15. However, another amorphous conductive material may also be used as the base member of the ScAlN film 15. Examples of the material constituting the amorphous film include conductive metal oxides and conductive metal nitrides. Examples of the conductive metal oxides include ruthenium oxide and indium tin oxide (ITO).

### Seventh Embodiment

In a piezoelectric film laminated body 10F of a seventh embodiment, as shown in FIG. 15, a ruthenium (Ru) film 26 is used as a base member of the ScAlN film 15 instead of the SiN film 14 of the first embodiment. The Ru film 26 is disposed above the Si substrate 11 and in contact with the surface of the Si substrate 11. The Ru film 26 has a base surface 26a in contact with the ScAlN film 15. Similarly to the first embodiment, the surface roughness of the base surface 26a is 0.5 nm or less in arithmetic average roughness.

The Ru film 26 is a film mainly composed of Ru which is a conductive material. The Ru film 26 is used as a lower electrode for exerting the piezoelectric function of the ScAlN film 15. Ru constituting the Ru film 26 has a hexagonal crystal structure and a polycrystalline structure having multiple crystal grains. The crystal grains include crystal grains in which crystal axes of the crystal grains are oriented in a specific orientation. The orientation of the c-axis of the oriented crystal grains is not perpendicular to the base surface 26a. In other words, the Ru film 26 has a structure excluding a structure in which the orientation of the c-axis of the hexagonal crystal is perpendicular to the base surface 26a.

Ru constituting the Ru film 26 may have a single crystal structure. Also in this case, the Ru film 26 has a structure excluding the structure in which the direction of the c-axis of the hexagonal crystal is perpendicular to the base surface 26a. That is, a crystal plane of the Ru film 26 in a plane direction parallel to the base surface 26a is not a c-plane.

A manufacturing method of the piezoelectric film laminated body 10F of the present embodiment includes process of forming the Ru film 26, a process of planarizing the Ru film 26, and a process of forming the ScAlN film 15. First, in the process of forming the Ru film 26, the Ru film 26 is formed on the surface of the Si substrate 11. Thereafter, the process of planarizing the Ru film 26 is performed. In the process of planarizing the Ru film 26, the base surface 26a of the Ru film 26 is planarized. At this time, the surface roughness of the base surface 26a is set to 0.5 nm or less in arithmetic average roughness by a method similar to the process S4 of planarizing the SiN film 14 of the first embodiment. Thereafter, the process of forming the ScAlN film 15 is performed. The process of forming the ScAlN film 15 is the same as the process S5 of the first embodiment.

According to the present embodiment, effects similar to those of the first embodiment can be obtained by setting the surface roughness of the base surface 21a to 0.5 nm or less in arithmetic average roughness. Furthermore, according to the piezoelectric film laminated body 10F of the present embodiment, the following effects can be obtained.

When the base member of the ScAlN film 15 has a hexagonal crystal structure and crystal grains are oriented such that the orientation of the c-axis of the hexagonal crystal is perpendicular to the surface 15a of the ScAlN film 15, abnormal grains are generated due to mismatch of lattice constants, as described in the first embodiment.

On the other hand, the Ru film 26, which is the base member of the ScAlN film 15, has a hexagonal crystal structure and has a structure excluding a structure in which the orientation of the c-axis of the hexagonal crystal is perpendicular to the base surface 26a. Therefore, it is possible to restrict the generation of abnormal grains caused by the mismatch of lattice constants which may occur when the base member of the ScAlN film 15 has a hexagonal structure. Not limited to the Ru film 26, another film made of a conductive material having a hexagonal crystal structure and having a structure excluding a structure in which the orientation of the c-axis of the hexagonal crystal is perpendicular to a base surface may also be used as a base member of the ScAlN film 15.

As a base member of the ScAlN film 15, a molybdenum (Mo) film may also be used instead of the Ru film 26 of the present embodiment. The Mo film is a film mainly composed of Mo. The Mo film has a base surface in contact with the ScAlN film 15. Also in this case, when the surface roughness of the base surface is 0.5 nm or less in arithmetic average roughness, effects similar to the effects of the first embodiment can be obtained.

In this case, Mo constituting the Mo film is a conductive material having a body-centered cubic crystal structure and having a polycrystalline structure having multiple crystal grains. The crystal grains include crystal grains in which crystal axes of the crystal grains are oriented in a specific orientation. The orientation of the <101> axis of the oriented grains is not perpendicular to the base surface. That is, Mo constituting the Mo film has a structure excluding a structure in which the orientation of the <101> axis of the body-centered cubic crystal is perpendicular to the base surface. Mo constituting the Mo film may have a single crystal structure. Also in this case, Mo constituting the Mo film has a structure excluding the structure in which the orientation of the <101> axis of the body-centered cubic crystal is perpendicular to the base surface. That is, a crystal plane in a plane direction parallel to the base surface of the Mo film is not a (101) plane.

In a case where the base material has a body-centered cubic crystal structure, when the orientation of the <101> axis of the body-centered cubic crystal is perpendicular to the base surface, the atomic arrangement in the plane direction parallel to the surface of the base member is six-fold rotationally symmetrical or close to pseudo six-fold rotationally symmetrical. Therefore, abnormal grains are generated due to the mismatch of the lattice constants described above.

On the other hand, the Mo film has the body-centered cubic crystal structure and has a structure excluding the structure in which the orientation of the <101> axis of the body-centered cubic crystal is perpendicular to the base surface. Therefore, it is possible to restrict the generation of abnormal grains caused by the mismatch of lattice constants which may occur when the base member of the ScAlN film 15 has a body-centered cubic crystal structure. Not limited to the Mo film, another film made of a conductive material, having a body-centered cubic crystal structure, and having a structure excluding a structure in which the orientation of the <101> axis of the body-centered cubic crystal is perpendicular to a base surface may also be used as a base member of the ScAlN film 15.

As a base member of the ScAlN film 15, a platinum (Pt) film may also be used instead of the Ru film 26 of the present embodiment. The Pt film is a film mainly composed of Pt. The Pt film has a base surface in contact with the ScAlN film 15. Also in this case, when the surface roughness of the base surface is 0.5 nm or less in arithmetic average roughness, effects similar to the effects of the first embodiment can be obtained.

In this case, Pt constituting the Pt film is a conductive material having a face-centered cubic crystal structure and a polycrystalline structure having multiple crystal grains. The crystal grains include crystal grains in which crystal axes of the crystal grains are oriented in a specific orientation. The orientation of the <111> axis of the oriented grains is not perpendicular to the base surface. That is, Pt constituting the Pt film has a structure excluding a structure in which the orientation of the <111> axis is perpendicular to the base surface.

Pt constituting the Pt film may have a single crystal structure. Also in this case, Pt constituting the Pt film has a structure excluding a structure in which the orientation of the <111> axis of the face-centered cubic crystal is perpendicular to the base surface. That is, a crystal plane in a plane direction parallel to the base surface of the Pt film is not a (111) plane.

In a case where the base material has a face-centered cubic crystal structure, when the orientation of the <111> axis of the face-centered cubic crystal is perpendicular to the base surface, the atomic arrangement in the plane direction parallel to the surface of the base member is six-fold rotationally symmetrical or close to pseudo six-fold rotationally symmetrical. Therefore, abnormal grains are generated due to the mismatch of the lattice constants described above.

On the other hand, the Pt film has the face-centered cubic crystal structure and has a structure excluding the structure in which the orientation of the <111> axis of the face-centered cubic crystal is perpendicular to the base surface. Therefore, it is possible to restrict the generation of abnormal grains caused by the mismatch of lattice constants which may occur when the base member of the ScAlN film 15 has a face-centered cubic crystal structure. Not limited to the Pt film, another film made of a conductive material, having a face-centered cubic crystal structure, and having a structure excluding a structure in which the orientation of the <111> axis of the face-centered cubic crystal is perpendicular to a base surface may also be used as a base member of the ScAlN film 15.

### Eighth Embodiment

A manufacturing method of the piezoelectric film laminated body 10 according to the eighth embodiment includes, as shown in FIG. 16, the process S1 of forming the AlN film 12, the process S2 of forming the Mo film 13, a process S2a of planarizing the Mo film 13, the process S3 of forming the SiN film 14, and the process S5 of forming the ScAlN film 15. The present embodiment is different from the first embodiment in that the process S2a of planarizing the Mo film 13 is performed instead of the process S4 of planarizing the SiN film 14. The processes other than the process S2a of planarizing the Mo film 13 are the same as those in the first embodiment.

After the process S2 of forming the Mo film 13, the process S2a of planarizing the Mo film 13 is performed. In the process S2a of planarizing the Mo film 13, the surface 13a of the Mo film 13 is planarized by etching using Ar plasma. At this time, the etching time is set so that the surface roughness of the surface 13a of the Mo film 13 becomes 0.5 nm or less in arithmetic average roughness. As a result, the surface roughness of the surface 13a of the Mo film 13 becomes 0.5 nm or less in arithmetic average roughness. After the surface 13a of the Mo film 13 is planarized, the process S3 of forming the SiN film 14 is performed. In the process S3 of forming the SiN film 14, the SiN film 14 having the base surface is formed in contact with the Mo film 13. Thereafter, the process S5 of forming the ScAlN film 15 is performed.

In the present embodiment, the process S1 of forming the AlN film 12 and the process S2 of forming the Mo film 13 correspond to preparing a conductive material having a surface. The process S2a of planarizing the Mo film 13 corresponds to planarizing the surface of the conductive material. The process S3 of forming the SiN film 14 corresponds to forming a base member in contact with the conductive material. The process S5 of forming the ScAlN film 15 corresponds to forming a ScAlN film in contact with the base surface.

According to the present embodiment, in the process S2a of planarizing the Mo film 13, the surface roughness of the surface of the Mo film 13 is set to 0.5 nm or less in arithmetic average roughness, so that the surface roughness of the SiN film 14 formed in the process S4, which is performed thereafter, can be 0.5 nm or less in arithmetic average roughness. As described above, when the base member is formed in contact with the surface of the conductive material, the surface roughness of the conductive material may be reflected in the surface roughness of the base member. In such a case, by setting the surface roughness of the conductive material to 0.5 nm or less, the surface roughness of the base surface of the base member can be 0.5 nm or less in arithmetic average roughness. Since the surface roughness of the base surface is set to 0.5 nm or less in arithmetic average roughness, also in the present embodiment, effects similar to those of the first embodiment can be obtained.

In the present embodiment, the SiN film 14, which is an amorphous insulating material, is formed as the base member of the ScAlN film 15. However, another material may also be formed as a base member of the ScAlN film 15. The material of the base member may be either an insulating material or a conductive material as in the second to seventh embodiments, and may be either amorphous or polycrystalline.

### Other Embodiments

In the first to seventh embodiments, the base surface is planarized by dry etching using Ar plasma. However, the base surface may be planarized by other methods. Other methods include chemical mechanical polishing (CVD). In a case where a silicon oxide film or the like doped with boron or phosphorus is used as the base member of the ScAlN film 15, the base surface may be planarized by heating to fluidize.

In the eighth embodiment, the surface of the conductive material such as the Mo film 13 is performed by etching using Ar plasma. However, the surface of the conductive material may be planarized also by another method such as CMP.

In each of the above embodiments, the base member of the ScAlN film 15 has the film shape. However, the base member may have a shape other than the film shape.

The present disclosure is not limited to the foregoing description of the embodiments and can be modified within the scope of the present disclosure. The present disclosure may also be varied in many ways. Such variations are not to be regarded as departure from the disclosure, and all such modifications are intended to be included within the scope of the disclosure. The above-described embodiments are not independent of each other, and can be appropriately combined except when the combination is obviously impossible. The constituent element(s) of each of the above embodiments is/are not necessarily essential unless it is specifically stated that the constituent element(s) is/are essential in the above embodiment, or unless the constituent element(s) is/are obviously essential in principle.

What is claimed is:

1. A piezoelectric film laminated body comprising:
a base member having a base surface; and
a scandium-containing aluminum nitride film disposed in contact with the base surface, wherein
a surface roughness of the base surface is 0.5 nm or less in arithmetic average roughness.

2. The piezoelectric film laminated body according to claim 1, wherein the base member is made of an amorphous insulating material.

3. The piezoelectric film laminated body according to claim 1, wherein
the base member is made of an insulating material that is a polycrystalline having a plurality of crystal grains, and each of the plurality of crystal grains has a non-oriented structure.

4. The piezoelectric film laminated body according to claim 1, wherein
the base member is made of an insulating material that has a crystal structure other than a hexagonal crystal and a cubic crystal.

5. The piezoelectric film laminated body according to claim 1, wherein
the base member is made of an insulating material having a crystal structure of a hexagonal crystal or a cubic crystal and having a polycrystalline structure or a single crystal structure including a plurality of crystal grains,
the plurality of crystal grains includes a crystal grain in which a crystal axis of the crystal grain is oriented in a specific orientation,
in a case where the base member has the crystal structure of the hexagonal crystal, the base member has a structure excluding a structure in which an orientation of a c-axis of the hexagonal crystal is perpendicular to the base surface, and
in a case where the base member has the crystal structure of the cubic crystal, the base member has a structure excluding a structure in which an orientation of a <111> axis of the cubic crystal is perpendicular to the base surface.

6. The piezoelectric film laminated body according to claim 2, wherein
the base member has a film shape, and
a film thickness of the base member is 1/10 or less of a film thickness of the scandium-containing aluminum nitride film.

7. The piezoelectric film laminated body according to claim 2, further comprising
a conductive member made of a conductive material, wherein
the conductive member is disposed in contact with a surface of the base member that is located opposite to the scandium-containing aluminum nitride film across the base member.

8. The piezoelectric film laminated body according to claim 7, wherein
the conductive member has a surface that is in contact with the base member, and
a surface roughness of the surface of the conductive member is 0.5 nm or less in arithmetic average roughness.

9. The piezoelectric film laminated body according to claim 1, wherein
the base member is made of an amorphous conductive material.

10. The piezoelectric film laminated body according to claim 1, wherein
the base member is made of a conductive material that is a polycrystalline having a plurality of crystal grains, and each of the plurality of crystal grains has a non-oriented structure.

11. The piezoelectric film laminated body according to claim 1, wherein
the base member is made of a conductive material having a crystal structurer of a hexagonal crystal, a body-centered cubic crystal or a face-centered cubic crystal, and having a polycrystalline structure or a single crystal structure including a plurality of crystal grains,
the plurality of crystal grains includes a crystal grain in which a crystal axis of the crystal grain is oriented in a specific orientation,
in a case where the base member has the crystal structure of the hexagonal crystal, the base member has a structure excluding a structure in which an orientation of a c-axis of the hexagonal crystal is perpendicular to the base surface,
in a case where the base member has the crystal structure of the body-centered cubic crystal, the base member has a structure excluding a structure in which an orientation of a <101> axis of the body-centered cubic crystal is perpendicular to the base surface, and
in a case where the base member has the crystal structure of the face-centered cubic crystal, the base member has a structure excluding a structure in which an orientation of a <111> axis of the face-centered cubic crystal is perpendicular to the base surface.

12. A manufacturing method of a piezoelectric film laminated body, comprising:
preparing a base member having a base surface;
planarizing the base surface; and
forming a scandium-containing aluminum nitride film in contact with the base surface after planarizing the base surface, wherein
the planarizing the base surface is performed such that a surface roughness of the base surface is 0.5 nm or less in arithmetic average roughness.

13. A manufacturing method of a piezoelectric film laminated body, comprising:
preparing a conductive member having a surface;
planarizing the surface of the conductive member;
forming a base member in contact with the surface of the conductive member after planarizing the surface, the base member having a base surface; and
forming a scandium-containing aluminum nitride film in contact with the base surface, wherein
the planarizing the conductive member is performed such that a surface roughness of the surface of the conductive member is 0.5 nm or less in arithmetic average roughness, so that a surface roughness of the base surface of the base member formed on the conductive member is 0.5 nm or less in arithmetic average roughness.
